(19) United States
(12) Patent Application Publication
(10) Pub. No.: US 2024/0321812 A1
(43) Pub. Date: Sep. 26, 2024

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Takeshi MURASAKI, Yokohama Kanagawa (JP)

(21) Appl. No.: 18/237,271

(22) Filed: Aug. 23, 2023

(30) Foreign Application Priority Data
Mar. 24, 2023 (JP) 2023-048412

(51) Int. Cl. H01L 23/00; H01L 23/64

(52) U.S. Cl. CPC H01L 24/48; H01L 23/642; H01L 23/645; H01L 2224/48227; H01L 2924/19041; H01L 2924/19042

(57) ABSTRACT

According to the present embodiment, a semiconductor device includes a substrate, a semiconductor chip, and a capacitor. The substrate includes at least a grounding terminal and is at the same potential as the grounding terminal. The semiconductor chip is arranged on the substrate and connected to the grounding terminal via a first bonding wire, and includes a circuit driven with a predetermined clock frequency and an analog circuit. The capacitor is arranged on the substrate and connected to at least either the circuit or the analog circuit at one end via a connection wire.

### CROSS-REFERENCE TO RELATED APPLICATIONS

This application is based upon and claims the benefit of priority from the prior Japanese Patent Application No. 2023-048412, filed on Mar. 24, 2023 the entire contents of which are incorporated herein by reference.

### FIELD

The embodiments of the present invention relate to a semiconductor device.

### BACKGROUND

In a semiconductor device including a semiconductor chip, a capacitor for noise reduction may be formed in or above the semiconductor chip. However, with increase in the degree of integration of semiconductor chips, it becomes difficult to ensure a space for a capacitor in a semiconductor chip. In addition, when a capacitor is formed above a semiconductor chip, the total thickness thereof increases, and therefore the size of a semiconductor device may increase.

### BRIEF DESCRIPTION OF THE DRAWINGS

FIG. 1 is a plan view illustrating a semiconductor device according to the present embodiment;

FIG. 2 is a diagram illustrating an example of an on-chip inductor;

FIG. 3 is a cross-sectional view of a portion of the semiconductor device when a capacitor is arranged vertically, the portion corresponding to the portion in FIG. 1 taken along a line B-B;

FIG. 4 is a diagram illustrating a configuration example of a semiconductor device according to a first modification of the first embodiment; and

FIG. 5 is a diagram illustrating a configuration example of a semiconductor device according to a second modification of the first embodiment.

### DETAILED DESCRIPTION

According to the present embodiment, a semiconductor device includes a substrate, a semiconductor chip, and a capacitor. The substrate includes at least a grounding terminal and is at the same potential as the grounding terminal. The semiconductor chip is arranged on the substrate and connected to the grounding terminal via a first bonding wire, and includes a circuit driven with a predetermined clock frequency and an analog circuit. The capacitor is arranged on the substrate and connected to at least either the circuit or the analog circuit at one end via a connection wire. Embodiments of the present invention will now be explained below with reference to the drawings. In the following embodiments, although characteristic configurations and operations of the semiconductor device are mainly explained, the semiconductor device can have configurations and operations that are omitted in the following explanations.

### First Embodiment

Embodiments of the present invention will be explained below with reference to the drawings. The drawings are schematic and conceptual. The relation between the thickness and the width of each constituent element, the ratio of size among the constituent elements, and the like do not necessarily match those of actual products. Even in a case where the same parts are represented, the dimensions and the ratios thereof are represented differently depending on the drawings in some cases. In the specification of the present application and the respective drawings, the same parts as those already explained are denoted by like reference characters and detailed explanations thereof are omitted as appropriate.

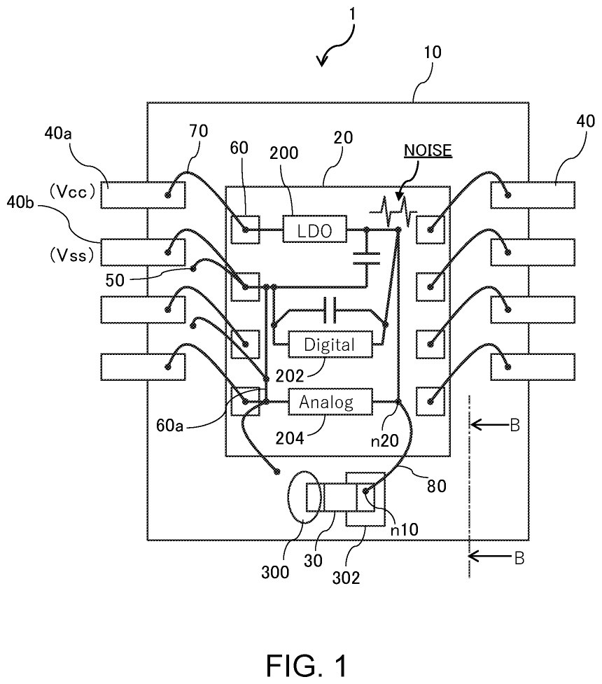

FIG. 1 is a plan view illustrating a semiconductor device 1 according to the present embodiment. As illustrated in FIG. 1, the semiconductor device 1 according to the present embodiment includes a substrate 10, a semiconductor chip 20, a capacitor 30, a plurality of bonding pads (electrode terminals) 40, a plurality of grounding lines 50, a GND wire 60a, a plurality of bonding wires 70, and a bonding wire 80.

The semiconductor chip 20 is, for example, an IC (Integrated Circuit) with a built-in regulator and includes a linear regulator (LDO: Low Dropout) 200, a digital circuit 202, and an analog circuit 204. For example, the linear regulator 200 and the digital circuit 202 can become a noise source for the analog circuit 204 because of switching of a transistor or the like. The linear regulator 200 and the digital circuit 202 have, for example, a CLK frequency fclk. Further, electrode pads 60 of the semiconductor chip 20 and the bonding pads 40 of the substrate 10 are connected to each other by the bonding wires 70, respectively. The linear regulator 200 according to the present embodiment corresponds to a power supply circuit.

The substrate 10 serves as a frame and is, for example, a conductive substrate. Alternatively, a conductor film that is conductive is formed on a predetermined range of the substrate 10.

The bonding pads 40 and the substrate 10 are insulated from each other by, for example, an insulating film. A bonding pad 40a among the bonding pads 40 corresponds to a power supply terminal (Vcc). A bonding pad 40b corresponds to a grounding terminal (Vss). The bonding pad 40b according to the present embodiment corresponds to a grounding terminal.

One end of each grounding line 50 is connected to the GND wire 60a connected to the bonding pad 40b. The GND wire 60a is, for example, a wire that connects an output terminal of the analog circuit 204 and the bonding pad 40b to each other.

Meanwhile, the other end of each grounding line 50 is connected to the substrate 10. As described above, bondings are formed by the grounding lines 50 from the GND wire 60a in the semiconductor chip 20 to the substrate 10 serving as a frame, so that a ground plane is formed by the frame. That is, the substrate 10 is placed at the same potential as the GND wire 60a by the grounding lines 50. In the present embodiment, the bonding wire 70 that connects the bonding pad 40b and the GND wire 60a to each other corresponds to a first bonding wire, the GND wire 60a corresponds to a second wire, and the grounding lines 50 correspond to third wires.

The capacitor 30 is, for example, a multilayer ceramic chip capacitor (MLCC). A connection node n10 on the one end side of the capacitor 30 and a node n20 on the input end side of the analog circuit 204 are connected to each other by the bonding wire 80. The one end side of the capacitor 30 is insulated by an insulation sheet 302. Meanwhile, the other end side of the capacitor 30 is directly connected to the substrate 10 by a conductive member 300, such as solder and silver paste, thereby being placed at the same potential as the substrate 10. The conductive member 300 according to the present embodiment corresponds to a conductive material, and the insulation sheet 302 corresponds to an insulator.

As described above, the digital circuit 202 has, for example, the clock (CLK) frequency fclk. The capacitance of the capacitor 30 is thus configured as a capacitance Cx that forms a series resonance circuit of MLCC together with an inductance Lx of the bonding wire 80. For example, it is considered that a resonance point is set to the CLK frequency folk of a digital part that can serve as a noise source or the frequency of its higher harmonic fclk*n. That is, the imaginary part at the resonance point becomes 0 at the CLK frequency fclk=1/(2n×Sqrt(Lx*Cx)), and the series resonance circuit is short-circuited to ground with an extremely low parasitic resistance (the real part). Thus, noise removal around the resonance frequency becomes easy. In general, the substrate 10 has a region where no circuit element or the like is formed other than a region where the bonding pads 40 are formed. Therefore, by forming the capacitor 30 in such a region, increase in size of the semiconductor device 1 can be prevented, and noise can be reduced.

The semiconductor chip 20 is a mere example, and the configuration of the semiconductor chip according to the present embodiment is not limited to the configuration described above. For example, in the semiconductor chip 20, noise reduction in a target wiring region is made possible by connecting the capacitor 30. Further, the parasitic capacitance and the inductance on the other end side of the analog circuit 204 can be adjusted by the grounding lines 50. For example, the grounding lines 50 can increase the parasitic capacitance by being arranged in parallel to the bonding wires 70. Furthermore, the bonding wire 80 according to the present embodiment corresponds to a connection wire.

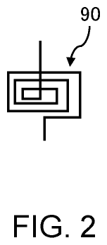

FIG. 2 is a diagram illustrating an example of an on-chip inductor 90. As illustrated in FIG. 2, adjustment of the inductance Lx is also made possible by connecting the on-chip inductor 90 to the bonding wire 80 in series.

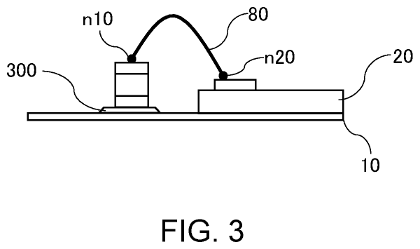

FIG. 3 is a cross-sectional view of a portion of the semiconductor device 1 when the capacitor 30 is arranged vertically, the portion corresponding to the portion in FIG. 1 taken along a line B-B. As illustrated in FIG. 3, the capacitor 30 may be arranged vertically. In this case, the insulation sheet 302 is not required.

As described above, according to the present embodiment, the capacitor 30 for noise reduction is arranged on the substrate 10 that forms a ground plane, and one end of the capacitor 30 is connected to the node n20 to which the digital circuit 202 is connected. This configuration can prevent increase in size and thickness of the semiconductor device 1 and can also reduce noise at the node n20 caused by the digital circuit 202. Further, by forming the node n20 on the input side of the analog circuit 204, noise for the analog circuit 204 connected via the node n20, caused by the digital circuit 202, can be reduced.

### First Modification of First Embodiment

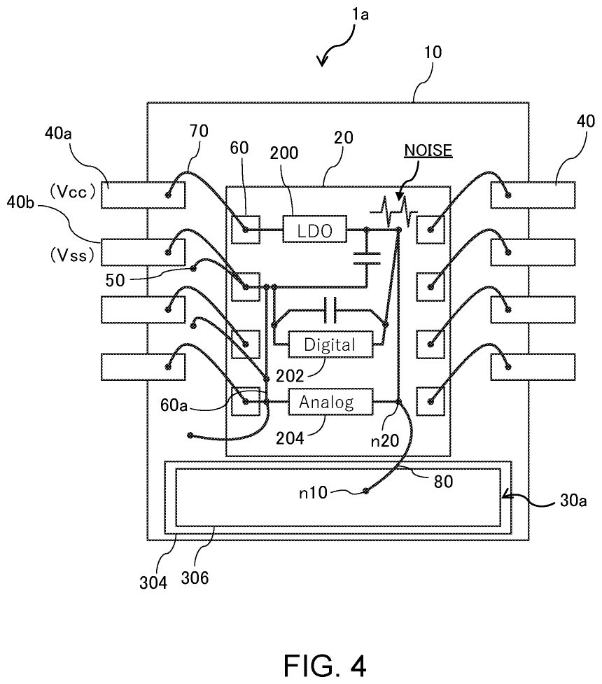

FIG. 4 is a diagram illustrating a configuration example of a semiconductor device 1a according to a first modification of the first embodiment. As illustrated in FIG. 4, a capacitor 30a has a high dielectric constant film 304 and a metal plate 306. The high dielectric constant film 304 is bonded to the substrate 10, and the metal plate 306 is arranged on the high dielectric constant film 304. The capacitor 30a is thus formed. Since the substrate 10 serving as an IC frame is used as an electrode as described above, the semiconductor device la can be made thinner, and the number of components of the capacitor 30a can be reduced.

### Second Modification of First Embodiment

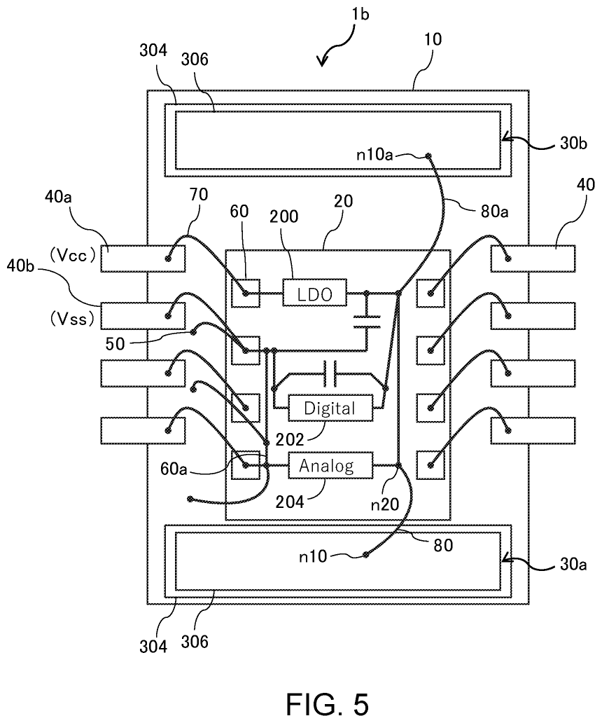

FIG. 5 is a diagram illustrating a configuration example of a semiconductor device 1b according to a second modification of the first embodiment. As illustrated in FIG. 5, the semiconductor device 1b further includes a capacitor 30b. The capacitor 30b includes the high dielectric constant film 304 and the metal plate 306. That is, the capacitor 30b is formed by bonding the high dielectric constant film 304 on the substrate 10 and arranging the metal plate 306 on the high dielectric constant film 304. Since the substrate 10 serving as an IC frame is used as an electrode as described above, the semiconductor device 1b can be made thinner, and the number of components of the capacitor 30b can be reduced. In addition, by forming the multiple capacitors 30a and 30b, capacitance adjustment and inductor adjustment of bonding wires 80 and 80a are made easy.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. As for the specific configurations of the respective elements such as the substrate 10, the semiconductor chip 20, the capacitors 30, 30a, and 30b, the plurality of grounding lines 50 that are included in the embodiment, those skilled in the art can select respective configurations from known art as appropriate. The accompanying claims and their equivalents are intended to cover such forms or modifications as would fall within the scope and spirit of the inventions. The respective embodiments described above can be combined with each other to be implemented.

1. A semiconductor device comprising:
a substrate including at least a grounding terminal and being at a same potential as the grounding terminal;
a semiconductor chip arranged on the substrate, connected to the grounding terminal via a first bonding wire, and including a circuit driven with a predetermined clock frequency and an analog circuit; and
a capacitor arranged on the substrate and connected at one end to at least either the circuit or the analog circuit via a connection wire.

2. The device of claim 1, wherein series resonance of an inductance of the connection wire and a capacitance of the capacitor is based on the clock frequency.

3. The device of claim 2, further comprising an on-chip inductor connected to the connection wire in series.

4. The device of claim 2, wherein the connection wire is connected to an input side wire of the analog circuit at one end and to the one end of the capacitor at the other end.

5. The device of claim 2, wherein the semiconductor chip further includes a second wire connected to the grounding terminal via the first bonding wire, and
the semiconductor device further comprises a third wire connecting the substrate and the second wire to each other.

6. The device of claim 5, wherein the circuit is at least either a digital circuit or a power supply circuit, and
the analog circuit is connected to the circuit at one end and to the second wire at the other end.

7. The device of claim 1, wherein the capacitor is a multilayer ceramic chip capacitor connected to the substrate at the other end.

8. The device of claim 7, wherein the capacitor is connected to the substrate at the other end via a conductive material.

9. The device of claim 8, wherein the one end of the capacitor, connected to the connection wire, is arranged on the substrate via an insulator.

10. The device of claim 1, wherein the capacitor includes a high dielectric constant film arranged with a first main surface facing the substrate and a metal plate arranged on a second main surface of the high dielectric constant film, the second main surface being opposite to the first main surface, and
the connection wire is connected to the metal plate.

11. The device of claim 9, wherein the capacitor is arranged in a plurality of regions on the substrate.
